(19) United States
(12) Patent Application Publication
(10) Pub. No.: US 2025/0053105 A1
(43) Pub. Date: Feb. 13, 2025

(54) SYSTEMS AND METHODS FOR MONITORING SPATIAL LIGHT MODULATOR (SLM) FLARE

(71) Applicant: NIKON CORPORATION, Tokyo (JP)

(72) Inventors: Donis G. FLAGELLO, Half Moon Bay, CA (US); Shiang-Lung KOO, Fremont, CA (US); Bausan YUAN, San Jose, CA (US)

(73) Assignee: NIKON CORPORATION, Tokyo (JP)

(21) Appl. No.: 18/933,209

(22) Filed: Oct. 31, 2024

Related U.S. Application Data
(63) Continuation of application No. PCT/US2023/020717, filed on May 2, 2023.
(60) Provisional application No. 63/337,682, filed on May 3, 2022.

(51) Int. Cl. G03F 7/00

(52) U.S. Cl. CPC G03F 7/70941; G03F 7/70258; G03F 7/70291; G03F 7/70666

(57) ABSTRACT

The problem of the presence of excess flare in maskless photolithography systems is addressed by systems and methods that utilize an aerial imaging system to monitor flare associated with the maskless photolithography systems.

### CROSS-REFERENCE TO RELATED APPLICATIONS

The present application claims priority to U.S. Provisional Patent Application No. 63/337,682, filed on May 3, 2022, entitled “SYSTEM AND METHODS FOR MONITORING SPATIAL LIGHT MODULATOR (SLM) FLARE,” which is incorporated herein by reference in its entirety for all purposes. The present application is a continuation application of International Application PCT/US2023/020717, filed on May 2, 2023. The contents of the above application are incorporated herein.

### BACKGROUND

Certain maskless photolithography systems and methods utilize one or more light sources, spatial light modulators (SLMs), and projection optics to project spatially patterned light to photoresist on a wafer. The spatial pattern imparted by the SLMs determines the locations at which the photoresist is exposed. To expose all of the photoresist on the wafer, the wafer is moved relative to the SLMs and the projection optics (for instance, using an actuator system that moves a stage on which the wafer is located). As the wafer is moved, the spatial pattern imparted by the SLMs is updated to expose the photoresist at desired locations on the wafer. However, the use of SLMs in maskless photolithography may introduce extra flare into the maskless photolithography system optics. Accordingly, presented herein are systems and methods for monitoring flare (SLM flare as an example) in maskless photolithography systems.

### BRIEF DESCRIPTION OF THE DRAWINGS

Various embodiments of the invention are disclosed in the following detailed description and the accompanying drawings.

FIG. 1A shows a schematic depicting an exemplary system for monitoring SLM flare in a maskless photolithography system when the system is operating in a first position.

FIG. 1B shows a schematic depicting the exemplary system for monitoring SLM flare in a maskless photolithography system when the system is operating in a second position.

FIG. 2A shows a flowchart depicting a first exemplary method for monitoring SLM flare in a maskless photolithography system.

FIG. 2B shows a flowchart depicting a second exemplary method for monitoring SLM flare in a maskless photolithography system.

FIG. 3 is a block diagram of a computer system used in some embodiments to perform portions of methods for monitoring SLM flare in a maskless photolithography system described herein.

FIG. 4A shows an example of a checkerboard SLM pattern or reference modulation pattern described herein.

FIG. 4B shows an example of simulated irradiance profiles obtained after passing light through the checkerboard pattern of FIG. 4A.

FIG. 4C shows an example of simulated center intensities of the irradiance profiles of FIG. 4B.

FIG. 4D shows an example of simulated contrasts of the irradiance profiles of FIG. 4C.

### DESCRIPTION OF THE EMBODIMENTS

The invention can be implemented in numerous ways, including as a process; an apparatus; a system; a composition of matter; a computer program product embodied on a computer readable storage medium; and/or a processor, such as a processor configured to execute instructions stored on and/or provided by a memory coupled to the processor. In this specification, these implementations, or any other form that the invention may take, may be referred to as techniques. In general, the order of the steps of disclosed processes may be altered within the scope of the invention. Unless stated otherwise, a component such as a processor or a memory described as being configured to perform a task may be implemented as a general component that is temporarily configured to perform the task at a given time or a specific component that is manufactured to perform the task. As used herein, the term “processor” refers to one or more devices, circuits, and/or processing cores configured to process data, such as computer program instructions.

A detailed description of one or more embodiments of the invention is provided below along with accompanying figures that illustrate the principles of the invention. The invention is described in connection with such embodiments, but the invention is not limited to any embodiment. The scope of the invention is limited only by the claims and the invention encompasses numerous alternatives, modifications and equivalents. Numerous specific details are set forth in the following description in order to provide a thorough understanding of the invention. These details are provided for the purpose of example and the invention may be practiced according to the claims without some or all of these specific details. For the purpose of clarity, technical material that is known in the technical fields related to the invention has not been described in detail so that the invention is not unnecessarily obscured.

As used herein, the term “or” shall convey both disjunctive and conjunctive meanings. For instance, the phrase “A or B” shall be interpreted to include element A alone, element B alone, and the combination of elements A and B.

As used herein, the term “flare” refers to unwanted reflected or scattered light that arrives at a wafer during a photolithography process. Flare may be caused by anything that forces light to travel in a direction that differs from that predicted by a ray tracing method. Flare may generally degrade exposure quality in photolithography by providing exposure to nominally dark features on a wafer, which reduces contrast. Flare may be quantified as the fraction of total light energy reaching the wafer that comes from unwanted reflections or scatterings within a photolithography system, or within a component of a photolithography system.

Certain maskless photolithography systems and methods utilize one or more light sources, spatial light modulators (SLMs), and projection optics to project spatially patterned light to photoresist on a wafer. The spatial pattern imparted by the SLMs determines the locations at which the photoresist is exposed. To expose all of the photoresist on the wafer, the wafer is moved relative to the SLMs and the projection optics (for instance, using an actuator system that moves a stage on which the wafer is located). As the wafer is moved, the spatial pattern imparted by the SLMs is updated to expose the photoresist at desired locations on the wafer. However, the use of SLMs in maskless photolithography may introduce extra flare into the maskless photolithography system optics. For example, an SLM may operate in a piston mode by raising or lowering micromirrors. This raising and lowering process may apply a 0 degree phase or a 180 degree phase to each pixel in the SLM. However, small errors in the raising and lowering process may result in phase errors that manifest as flare. Small gaps between the micromirrors, holes in the center of the micromirrors, and defects in the coatings of the micromirrors may also contribute flare. Moreover, the flare associated with the SLM may change over time as its components age.

Accordingly, the problem of the presence of excess flare in maskless photolithography systems is addressed by systems and methods that utilize an aerial imaging system to monitor flare associated with the maskless photolithography systems. The systems and methods generally utilize a stage configured to support an SLM and a reference plate featuring a reference modulation pattern. The stage is movable between two positions, allowing either the SLM or the reference plate to receive source light from a light source. When the stage is positioned to allow the SLM to receive the source light, the SLM imparts an SLM modulation pattern on the source light and projects spatially modulated light to a projection lens. The projection lens projects a first image corresponding to the spatially modulated light. The first image is received by the aerial imaging system. When the stage is positioned to allow the reference plate to receive the source light, the reference plate imparts a reference modulation pattern on the source light and projects reference modulated light to the projection lens. The projection lens projects a second image corresponding to the reference modulated light. The second image is received by the aerial imaging system. The spatially modulated light comprises a first flare pattern containing contributions from the SLM, while the reference modulated light comprises a second flare pattern containing a contribution from the reference plate. Assuming the reference plate is substantially free from defects, flare associated with the SLM can be determined by subtracting the second flare pattern from the first flare pattern. The resulting flare can be used to alter one or more parameters associated with the SLM, such as an exposure time or exposure intensity of the spatially modulated light on a photoresist.

Provided herein is a system for monitoring spatial light modulator (SLM) flare in a maskless photolithography system, comprising: a stage configured to support an SLM and a reference plate, the stage movable between: a first position in which the SLM receives source light, imparts an SLM pattern thereon, and projects spatially modulated light based on the SLM pattern, the spatially modulated light comprising a first flare pattern associated with the SLM; and a second position in which the reference plate receives the source light, imparts a reference modulation pattern thereon, and projects reference modulated light based on the reference modulation pattern, the reference modulated light comprising a second flare pattern associated with the reference plate; a projection lens configured to: when the stage is in the first position, receive the spatially modulated light and project a first image corresponding to the spatially modulated light; when the stage is in the second position, receive the reference modulated light and project a second image corresponding to the reference modulated light; an aerial imaging system configured to: when the stage is in the first position, receive the first image and output a first signal corresponding thereto; and when the stage is in the second position, receive the second image and output a second signal corresponding thereto; and a controller operably coupled to the stage and to the aerial imaging system, the controller configured to: (a) direct the stage to move to the first position; (b) receive the first signal; (c) direct the stage to move to the second position; (d) receive the second signal; and (c) determine a third flare pattern associated with SLM errors based on a difference between the first signal and the second signal. In some embodiments, the system further comprises a light source configured to project the source light. In some embodiments, the controller is further operably coupled to the SLM and wherein the controller is further configured to alter one or more parameters associated with the SLM in response to the third flare pattern. In some embodiments, the one or more parameters comprise one or more members selected from the group consisting of: an exposure time of the spatially modulated light on a photoresist, an exposure intensity of the spatially modulated light on a photoresist, and a phase of one or more pixels associated with the SLM. In some embodiments, the reference modulation pattern comprises a static modulation pattern. In some embodiments, the aerial imaging system comprises at least one deep ultraviolet (DUV) camera. In some embodiments, the SLM pattern or the reference modulation pattern is selected from the group consisting of: a checkerboard pattern, a flat line pattern, a parallelogram pattern, a diamond pattern, and a pattern comprising at least one alignment mark. In some embodiments, the source light comprises OBKK light or BBSK light. In some embodiments, the controller comprises: a processor; and a memory coupled with the processor, wherein the memory is configured to provide the processor with instructions which when executed cause the processor to perform (a)-(c). In some embodiments, the controller comprises: a processor configured to perform (a)-(c); and a memory coupled to the processor and configured to provide the processor with instructions to perform (a)-(c).

Further provided herein is a method for monitoring spatial light modulator (SLM) flare in a maskless photolithography system, comprising: (a) projecting source light to an SLM, thereby imparting an SLM pattern thereon and projecting spatially modulated light based on the SLM pattern, the spatially modulated light comprising a first flare pattern associated with the SLM; (b) using a projection lens to receive the spatially modulated light and to project a first image corresponding to the spatially modulated light; (c) using an aerial imaging system to receive the first image and to output a first signal corresponding thereto; (d) projecting the source light to a reference plate, thereby imparting a reference modulate pattern thereon and projecting reference modulated light based on the reference modulation pattern, the reference modulated light comprising a second flare pattern associated with the reference plate; € using the projection lens to receive the reference modulated light and to project a second image corresponding to the reference modulated light; (f) using the aerial imaging system to receive the second image and to output a second signal corresponding thereto; and (g) determining a third flare pattern associated with SLM errors based on a difference between the first signal and the second signal. In some embodiments, the method further comprises using a light source to project the source light. In some embodiments, the method further comprises altering one or more parameters associated with the SLM in response to the third flare pattern. In some embodiments, the one or more parameters comprise one or more members selected from the group consisting of: an exposure time of the spatially modulated light on a photoresist, an exposure intensity of the spatially modulated light on a photoresist, and a phase of one or more pixels associated with the SLM. In some embodiments, the reference modulation pattern comprises a static modulation pattern. In some embodiments, the aerial imaging system comprises at least one deep ultraviolet (DUV) camera. In some embodiments, the SLM pattern or the reference modulation pattern is selected from the group consisting of: a checkerboard pattern, a flat line pattern, a parallelogram pattern, a diamond pattern, and a pattern comprising at least one alignment mark.

Further provided herein is an exposure apparatus comprising: An exposure apparatus comprising: an illumination optical system configured to illuminate a spatial light modulator (SLM) which has a plurality of SLM elements having a reflecting surface disposed on a disposition plane; a projection optical system configured to project light from the SLM to a workpiece; a reference member having a reference modulation pattern; a position changing apparatus configured to change a positional relationship among the SLM, the reference member, and the projection optical system to either a first positional relationship in which a light from the illumination optical system enters in the projection optical system via the SLM and a second positional relationship in which a light from the illumination optical system enters in the projection optical system via the reference member; and a detection apparatus configured to detect a light from the SLM or the reference member via the projection optical system.

In some embodiments, the exposure apparatus comprises a calculation apparatus configured to calculate a state of the SLM based on a first output from the detection apparatus in the first positional relationship and a second output from the detection apparatus in the second positional relationship. In some embodiments, the state of the SLM comprises a flare from the SLM. In some embodiments, the detection apparatus is configured to detect an aerial image of the SLM and the reference pattern of the reference member formed by the projection optical system. In some embodiments, the detection apparatus is configured to detect the aerial image of the SLM in the first positional relationship, and to detect the aerial image of the reference modulation pattern in the second positional relationship. In some embodiments, the exposure apparatus further comprises a controller configured to control a pattern of the plurality of SLM elements and the position changing apparatus. In some embodiments, the controller is configured to set the pattern of the plurality of SLM elements to the same pattern as the reference modulation pattern. In some embodiments, the reference modulation pattern comprises at least one of a checkerboard pattern, a flat line pattern, a parallelogram pattern, a diamond pattern, and a pattern comprising at least one alignment mark.

Further provided herein is an exposure method comprising: illuminating a spatial light modulator (SLM) which has a plurality of SLM having a reflecting surface disposed on a disposition plane; using a projection optical system to project a light from the SLM to a workpiece; setting a positional relationship between the SLM and the projection optical system to a first positional relationship in which a light from the SLM enters in the projection optical system; outputting a first output by detecting a light from the SLM via the projection optical system in the first positional relationship; setting a positional relationship between a reference member having a reference modulation pattern and the projection optical system to a second positional relationship in which a light from the reference member enters in the projection optical system; and outputting a second output by detecting a light from the SLM via the projection optical system in the second positional relationship. In some embodiments, the exposure method further comprises obtaining a state of the SLM based on the first and second output.

Further provided herein is device manufacturing method comprising: forming a resist on a surface of a substrate; and exposing an exposure pattern using the exposure method.

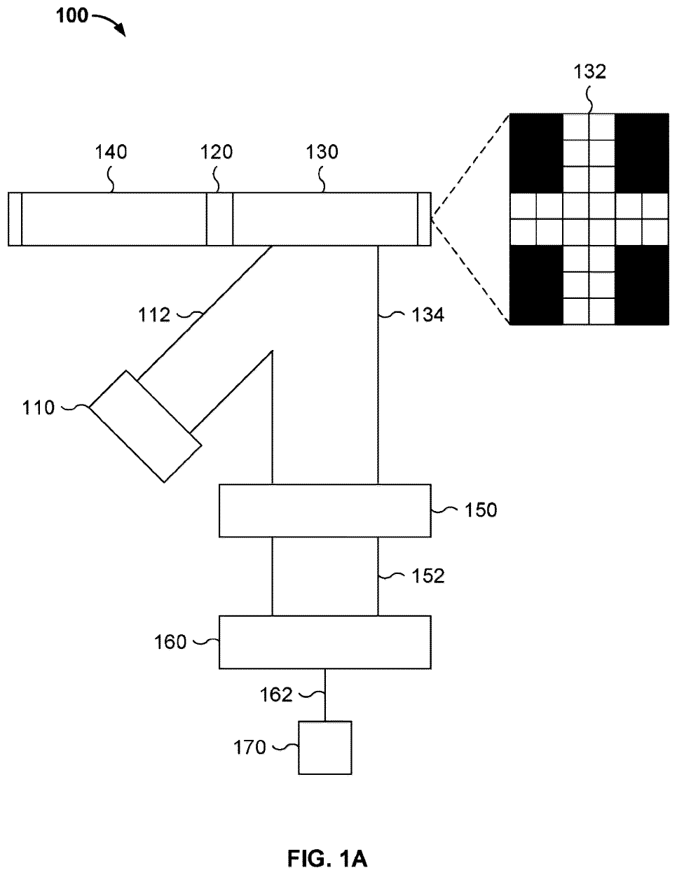

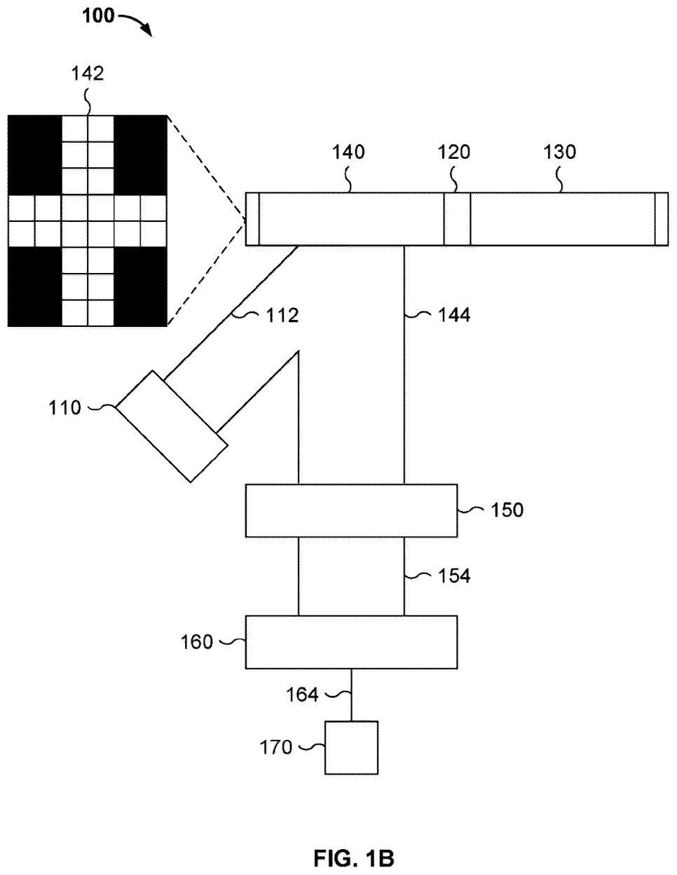

FIG. 1A shows a schematic depicting an exemplary system 100 for monitoring SLM flare in a maskless photolithography system when the system 100 is operating in a first position. In some embodiments, the system 100 is referred to herein as an exposure apparatus. In the example shown, the system 100 comprises an illumination optical system 110. In some embodiments, the illumination optical system 110 comprises a light source. In some embodiments, the illumination optical system 110 is configured to project source light 112. In some embodiments, the illumination optical system 110 comprises at least one light emitting diode (LED). In some embodiments, the illumination optical system 110 comprises at least one laser source. In some embodiments, the laser source comprises at least one continuous wave laser source. In some embodiments, the laser source comprises at least one pulsed laser. In some embodiments, the laser source comprises at least one gas laser (typically, an argon fluoride (ArF) excimer laser or krypton fluoride (KrF) excimer laser). In some embodiments, the laser source comprises at least one metal-vapor laser. In some embodiments, the laser source comprises at least one solid-state laser. In some embodiments, the laser source comprises at least one semiconductor laser or diode laser. Although depicted as comprising an illumination optical system 110 in FIG. 1A, in some embodiments, the system 100 does not comprise the illumination optical system 110.

In the example shown, the system 100 comprises a position changing apparatus 120. In some embodiments, the position changing apparatus 120 comprises a stage. In some embodiments, the position changing apparatus 120 is configured to support an SLM 130 and a reference member 140. In some embodiments, when the position changing apparatus 120 is in the first position, the SLM 130 receives the source light 112, imparts an SLM pattern 132 thereon, and projects spatially modulated light 134 based on the SLM pattern 132. In some embodiments, the SLM pattern 132 comprises a checkerboard pattern, a flat line pattern, a parallelogram pattern, a diamond pattern, or a pattern comprising at least one alignment mark. In some embodiments, the spatially modulated light 134 comprises a first flare pattern associated with the SLM 130. In the example shown, the SLM 130 comprises a reflective SLM. However, in some embodiments, the SLM 130 comprises a transmissive SLM. In some embodiments, the SLM comprises a plurality of SLM elements having a reflecting surface disposed on a disposition plane. In some embodiments, the illumination optical system 110 is configured to illuminate the SLM.

In the example shown, the SLM 130 imparts an SLM pattern 132 having an 8×6 display resolution for simplicity. However, the SLM pattern 132 may have any display resolution. In some embodiments, the SLM 130 has a pixel pitch of at least about 0.1 micrometer (μm) or more. In some embodiments, the SLM 130 has a pixel pitch of at most about 10 μm or less. In some embodiments, the SLM 130 has a pixel pitch between about 0.1 um and about 10 μm. Moreover, the inset shows the SLM pattern 132 rotated by 90 degrees for purposes of illustration.

In the example shown, the system 100 comprises a projection optical system 150. In some embodiments, the projection optical system 150 comprises a projection lens. In some embodiments, when the position changing apparatus 120 is in the first position, the projection optical system 150 is configured to receive the spatially modulated light 134 and to project a first image 152 corresponding to the spatially modulated light 134. In some embodiments, the projection optical system is configured to project light from the SLM to a workpiece (not shown in FIG. 1A).

In the example shown, the system 100 comprises a detection apparatus 160. In some embodiments, the detection apparatus 160 comprises an aerial imaging system. In some embodiments, when the position changing apparatus 120 is in the first position, the detection apparatus 160 is configured to receive the first image 152 and to output a first signal 162 corresponding to the first image 152. In some embodiments, the first image 152 comprises an aerial image of the SLM 130. In some embodiments, the detection apparatus 160 comprises at least one ultraviolet (UV) camera or at least one deep UV (DUV) camera. In some embodiments, the detection apparatus 160 is substantially similar to or identical to any of the systems disclosed in U.S. Pat. Nos. 8,809,616, 7,573,052, and 7,791,718, each of which is incorporated by reference in its entirety for all purposes.

In the example shown, the system 100 comprises a controller 170. In some embodiments, the controller 170 is operably coupled to the position changing apparatus 120 and to the detection apparatus 160. In some embodiments, when the position changing apparatus 120 is in the first position, the controller 170 is configured to receive the first signal 162.

Thus, when in the first position, the detection apparatus 160 is configured to detect a light from the SLM 130 via the projection optical system 150.

FIG. 1B shows a schematic depicting the exemplary system 100 for monitoring SLM flare in a maskless photolithography system when the system 100 is operating in a second position.

As in FIG. 1A, the system 100 generally comprises an illumination optical system 110 configured to project source light 112, a position changing apparatus 120 configured to support an SLM 130 and a reference member 140, a projection optical system 150, a detection apparatus 160, and a controller 170.

In the example shown, when the position changing apparatus 120 is in the second position, the reference member 140 receives the source light 112, imparts a reference modulation pattern 142 thereon, and projects reference modulated light 144 based on the reference modulation pattern 142. In some embodiments, the reference member 140 comprises a reference plate. In some embodiments, the reference modulation pattern 142 comprises a checkerboard pattern, a flat line pattern, a parallelogram pattern, a diamond pattern, or a pattern comprising at least one alignment mark. In some embodiments, the reference modulated light 144 comprises a second flare pattern associated with the reference member 140. In some embodiments, the reference modulation pattern 142 comprises a static modulation pattern. In some embodiments, the reference member 140 comprises a series of transmissive regions and a series of absorptive regions. In some embodiments, the transmissive and absorptive regions emulate the behavior of an ideal SLM.

In the example shown, the reference member 140 imparts a reference modulation pattern 142 having an 8×6 display resolution for simplicity. However, the reference modulation pattern 142 may have any display resolution. For instance, in some embodiments, the reference modulation pattern 142 has a display resolution same as a display resolution of the SLM pattern 132. For instance, in some embodiments, the display resolution of the reference modulation pattern is larger than or smaller than the display resolution of the SLM pattern 132. Moreover, the inset shows the reference modulation pattern 154 rotated by 90 degrees for purposes of illustration.

In the example shown, when the position changing apparatus 120 is in the first position, the projection optical system 150 is configured to receive the reference modulated light 144 and to project a second image 154 corresponding to the reference modulated light 144.

In the example shown, when the position changing apparatus 120 is in the second position, the detection apparatus 160 is configured to receive the second image 154 and to output a second signal 164 corresponding to the second image 154. In some embodiments, the first image 152 comprises an aerial image of the reference member 140.

As in FIG. 1A, the system 100 comprises a controller 170. In some embodiments, the controller 170 is operably coupled to the position changing apparatus 120 and to the detection apparatus 160. In some embodiments. In the example shown, when the position changing apparatus 120 is in the second position, the controller 170 is configured to receive the second signal 164.

In some embodiments, the controller 170 is configured to control the position changing apparatus 120 and the detection apparatus 160 sequentially. Thus, in some embodiments, the controller 170 is configured to perform the following series of operations: (a) directing the position changing apparatus 120 to move to the first position, (b) receiving the first signal 162 from the detection apparatus 160, (c) directing the position changing apparatus 120 to move to the second position, (d) receiving the second signal 164 from the detection apparatus 160, and (e) determining a third flare pattern associated with SLM errors based on a difference between the first signal 162 and the second signal 164. In some embodiments, the series of operations is repeated one or more times during operation of a maskless photolithography system.

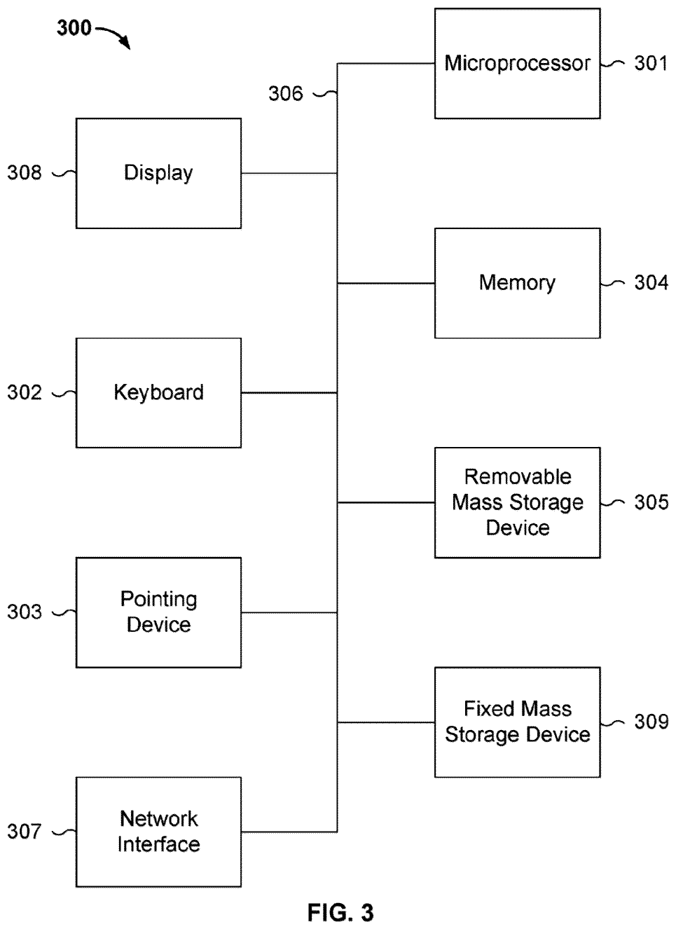

In some embodiments, the controller 170 is operably coupled to the SLM 130. In some embodiments, the controller 170 is configured to alter one or more parameters associated with the SLM 130 in response to the third flare pattern. For instance, in some embodiments, the controller 170 is configured to alter an exposure time of the spatially modulated light 134 on a photoresist (not shown in FIGS. 1A or 1B), an exposure intensity of the spatially modulated light 134 on a photoresist, or a phase of one or more pixels associated with the SLM 134. In some embodiments, the controller 170 is configured to control a pattern of the plurality of SLM elements of the SLM 130 and the position changing apparatus 120. In some embodiments, the controller 170 is configured to set the pattern of the plurality of SLM elements to the same pattern as the reference modulation pattern 142. In some embodiments, the controller 170 comprises computer system 300 described herein with respect to FIG. 3, or any components thereof.

Thus, when in the second position, the detection apparatus 160 is configured to detect a light from the reference member 140 via the projection optical system 150.

Taken in combination, FIGS. 1A and 1B demonstrate that, in some embodiments, the position changing apparatus 120 is configured to change a positional relationship among the SLM 130, the reference member 140, and the projection optical system 150 to either a first positional relationship in which a light from the illumination optical system 110 enters in the projection optical system 150 via the SLM 130 and a second positional relationship in which a light from the illumination optical system 110 enters in the projection optical system 150 via the reference member 140.

In some embodiments, the system 100 further comprises a calculation apparatus (not shown in FIG. 1A or 1B). In some embodiments, the calculation apparatus comprises computer system 300 described herein with respect to FIG. 3, or any components thereof. In some embodiments, the calculation apparatus is configured to calculate a state of the SLM 130 based on a first output from the detection apparatus 160 in the first positional relationship (e.g., the first signal 162) and a second output from the detection apparatus 160 in the second positional relationship (e.g., the second signal 164). In some embodiments, the calculation apparatus is configured to calculate the state of the SLM based on a difference between the first signal 162 and the second signal 164, as described herein. In some embodiments, the state of the SLM 130 comprises a flare from the SLM 130.

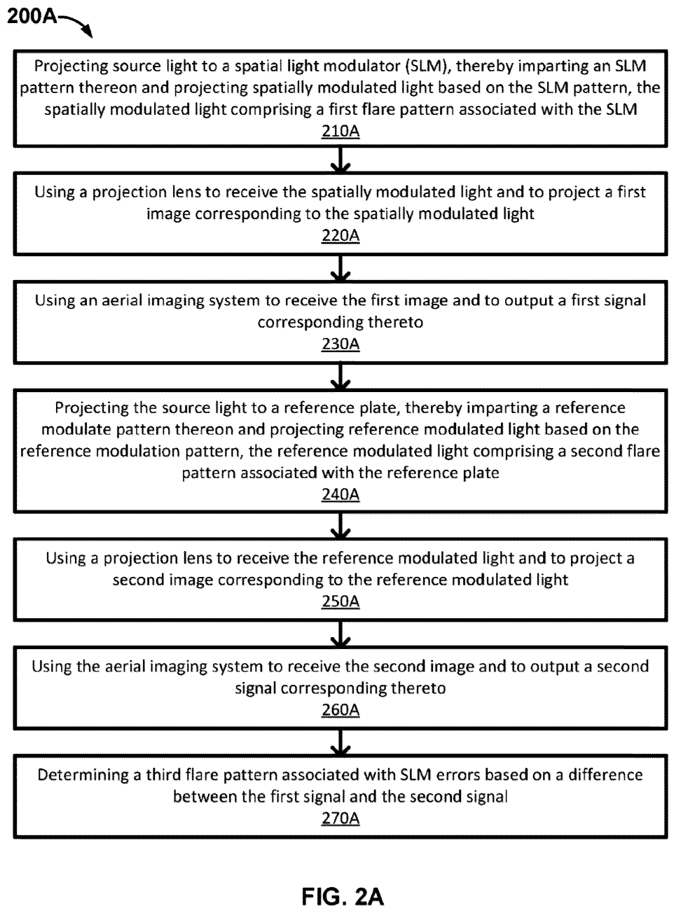

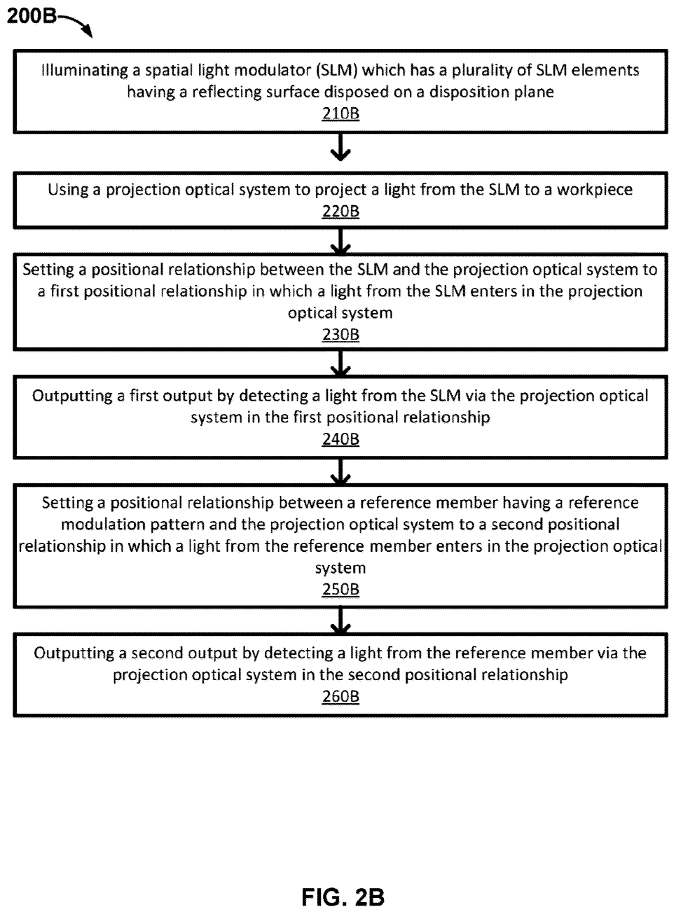

FIG. 2A shows a flowchart depicting a first exemplary method 200A for monitoring SLM flare in a maskless photolithography system. In the example shown, source light is projected to an SLM at 210A. In some embodiments, projecting the source light to the SLM thereby imparts an SLM pattern on the source light and projects spatially modulated light based on the SLM pattern. In some embodiments, the spatially modulated light comprises a first flare pattern associated with the SLM. In some embodiments, the SLM comprises any SLM described herein with respect to FIGS. 1A or 1B. In some embodiments, the SLM pattern comprises any SLM pattern described herein with respect to FIGS. 1A or 1B. In some embodiments, the spatially modulated light comprises any spatially modulated light described herein with respect to FIGS. 1A or 1B. In some embodiments, the first flare pattern comprises any first flare pattern described herein with respect to FIGS. 1A or 1B.

At 220A, a projection lens is used to receive the spatially modulated light. In some embodiments, the projection lens is used to project a first image corresponding to the spatially modulated light. In some embodiments, the projection lens comprises any projection lens described herein with respect to FIGS. 1A or 1B. In some embodiments, the first image comprises any first image described herein with respect to FIGS. 1A or 1B.

At 230A, an aerial imaging system is used to receive the first image and to output a first signal corresponding to the first image. In some embodiments, the aerial imaging system comprises any aerial imaging system described herein with respect to FIGS. 1A or 1B. In some embodiments, the first signal comprises any first signal described herein with respect to FIGS. 1A or 1B.

At 240A, the source light is projected to the reference plate. In some embodiments, projecting the source light to the reference plate thereby imparts a reference modulation pattern on the source light and projects reference modulated light based on the reference modulation pattern. In some embodiments, the reference modulated light comprises a second flare pattern associated with the reference plate. In some embodiments, the reference plate comprises any reference plate described herein with respect to FIGS. 1A or 1B. In some embodiments, the reference modulation pattern comprises any reference modulation pattern described herein with respect to FIGS. 1A or 1B. In some embodiments, the reference modulated light comprises any reference modulated light described herein with respect to FIGS. 1A or 1B. In some embodiments, the second flare pattern comprises any second flare pattern described herein with respect to FIGS. 1A or 1B.

At 250A, the projection lens is used to receive the reference modulated light. In some embodiments, the projection lens is used to project a second image corresponding to the reference modulated light. In some embodiments, the second image comprises any second image described herein with respect to FIGS. 1A or 1B.

At 260A, the acrial imaging system is used to receive the second image and to output a second signal corresponding to the second image. In some embodiments, the second signal comprises any second signal described herein with respect to FIGS. 1A or 1B. At 270A, a third flare pattern associated with SLM errors is determined based on a difference between the first signal and the second signal. In some embodiments, the third flare pattern comprises any third flare pattern described herein with respect to FIGS. 1A or 1B.

In some embodiments, the method 200A further comprises altering one or more parameters associated with the SLM in response to the third flare pattern. In some embodiments, the one or more parameters comprise an exposure time of the spatially modulated light on a photoresist, an exposure intensity of the spatially modulated light on a photoresist, or a phase of one or more pixels associated with the SLM.

In some embodiments, the method 200A, or any one or more of operations 210A, 220A, 230A, 240A, 250A, and 260A, and 270A are performed using the system 100 described herein with respect to FIGS. 1A or 1B, or with the computer system 300 described herein with respect to FIG. 3.

FIG. 2B shows a flowchart depicting a second exemplary method 200B for monitoring SLM flare in a maskless photolithography system. In the example shown, a SLM is illuminated at 210B. In some embodiments, the SLM comprises any SLM described herein with respect to FIGS. 1A or 1B.

At 220B, a projection optical system is used to project a light from the SLM to a workpiece. In some embodiments, the projection optical system comprises any projection optical system described herein with respect to FIGS. 1A or 1B.

At 230B, a positional relationship between the SLM and the projection optical system is set to a first positional relationship in which a light from the SLM enters in the projection optical system. In some embodiments, the positional relationship is set using the position changing apparatus described herein with respect to FIGS. 1A or 1B.

At 240B, light is detected from the SLM via the projection optical system in the first positional relationship and a first output is obtained. In some embodiments, the light is detected using the detection apparatus described herein with respect to FIGS. 1A or 1B.

At 250B, a positional relationship between a reference member and the projection optical system is set to a second positional relationship in which a light from the reference member enters in the projection optical system. In some embodiments, the reference member comprises any reference member described herein with respect to FIGS. 1A or 1B. In some embodiments, the positional relationship is set using the position changing apparatus described herein with respect to FIGS. 1A or 1B.

At 260B, light is detected from the reference member via the projection optical system in the second positional relationship and a second output is obtained. In some embodiments, the light is detected using the detection apparatus described herein with respect to FIGS. 1A or 1B.

In some embodiments, the method 200B further comprises obtaining a state of the SLM based on the first and second outputs.

In some embodiments, a device manufacturing method comprises forming a resist (e.g., a photoresist) on a surface of a substrate and exposing an exposure pattern using the method 200B.

In some embodiments, the system 100, the method 200A, or the method 200B is used to measure SLM flare in different locations over all or a portion of the surface of a SLM to obtain flare measurements as a function of position on the SLM. In some embodiments, the acrial imaging system described herein uses a scanning imaging protocol to measure the SLM flare in different locations on the SLM.

In some embodiments, the system 100, the method 200A, or the method 200B is used to measure a uniformity of illumination provided by the light source, or by the light source and the projection lens. In some embodiments, the uniformity of illumination may be measured by setting all pixels of the SLM to a uniform phase or height. In some embodiments, the measured uniformity of the illumination may allow the SLM to compensate for non-uniformities in the illumination.

In some embodiments, the system 100, the method 200A, or the method 200B is used to provide a calibration profile for the SLM. In some embodiments, a white light interferometer (such as a Mirau interferometer, Michelson interferometer, Linnik interferometer, or the like) is used to measure height or phase errors in pixels of the SLM. In some embodiments, the measured height or phase errors may allow the SLM to compensate for such non-idealities. In some embodiments, the white light interferometer comprises any interferometer disclosed in U.S. Pat. Nos. 11,099,007, 10,267,625, and 10,302,419, each of which is incorporated herein by reference in its entirety for all purposes.

In some embodiments, the system 100, the method 200A, or the method 200B is used to calibrate a relative position between the white light interferometer and an SLM defects detecting system. In some embodiments, a reference modulation pattern or an SLM modulation pattern that contains an alignment mark is used to calibrate the relative position.

In some embodiments, the SLM defects detecting system comprises any inspection apparatus disclosed in Japanese Patent No. 6969163, which is herein incorporated by reference in its entirety for all purposes.

In some embodiments, the system 100, the method 200A, or the method 200B is used to calibrate illumination uniformity of the SLM defects detecting system. In some embodiments, the illumination uniformity is calibrated using an SLM pattern 132 that displays a flat pattern (i.e., a pattern when all the mirrors of the SLM 130 are in the same state).

In some embodiments, the system 100 can be used to calibrate the height measurements of the SLM defects detecting system. In some embodiments, the height measurement is calibrated using an SLM pattern 132 that displays a checkerboard pattern.

In some embodiments, the system 100, the method 200A, or the method 200B is used to provide blind position adjustment for an illumination pattern. In some embodiments, the blind position adjustment uses a parallelogram illumination pattern and a test pattern that contains a parallelogram pattern. In some embodiments, the blind position adjustment uses a test pattern that contains a checkerboard pattern.

In some embodiments, the system 100, the method 200A, or the method 200B is used to provide a measurement of optical power or optical intensity of the projected light described herein. In some embodiments, the measurement of optical power or optical intensity is measured using a test pattern that contains a solid pattern. In some embodiments, the measurement of optical power or optical intensity is used to monitor any changes in the SLM, such as deterioration in the inherent reflectance of the SLM (e.g., due to changes in the SLM surface or coating). In some embodiments, changes in the SLM are detected by comparing measurements of the optical power or optical intensity through the SLM versus those through the test pattern.

FIG. 3 is a block diagram of a computer system 300 used in some embodiments to perform portions of methods for monitoring SLM flare in a maskless photolithography system described herein (such as operation 270A of method 200A as described herein with respect to FIG. 2A). In some embodiments, the computer system may be utilized as a component in systems for monitoring SLM flare in a maskless photolithography system described herein (such as controller 170 of system 100 as described herein with respect to FIGS. 1A or 1B). FIG. 3 illustrates one embodiment of a general purpose computer system. Other computer system architectures and configurations can be used for carrying out the processing of the present invention. Computer system 300, made up of various subsystems described below, includes at least one microprocessor subsystem 301. In some embodiments, the microprocessor subsystem comprises at least one central processing unit (CPU) or graphical processing unit (GPU). The microprocessor subsystem can be implemented by a single-chip processor or by multiple processors. In some embodiments, the microprocessor subsystem is a general purpose digital processor which controls the operation of the computer system 300. Using instructions retrieved from memory 304, the microprocessor subsystem controls the reception and manipulation of input data, and the output and display of data on output devices.

The microprocessor subsystem 301 is coupled bi-directionally with memory 304, which can include a first primary storage, typically a random access memory (RAM), and a second primary storage area, typically a read-only memory (ROM). As is well known in the art, primary storage can be used as a general storage area and as scratch-pad memory, and can also be used to store input data and processed data. It can also store programming instructions and data, in the form of data objects and text objects, in addition to other data and instructions for processes operating on microprocessor subsystem. Also as well known in the art, primary storage typically includes basic operating instructions, program code, data and objects used by the microprocessor subsystem to perform its functions. Primary storage devices 304 may include any suitable computer-readable storage media, described below, depending on whether, for example, data access needs to be bi-directional or uni-directional. The microprocessor subsystem 301 can also directly and very rapidly retrieve and store frequently needed data in a cache memory (not shown).

A removable mass storage device 305 provides additional data storage capacity for the computer system 300, and is coupled either bi-directionally (read/write) or uni-directionally (read only) to microprocessor subsystem 301. Storage 305 may also include computer-readable media such as magnetic tape, flash memory, signals embodied on a carrier wave, PC-CARDS, portable mass storage devices, holographic storage devices, and other storage devices. A fixed mass storage 309 can also provide additional data storage capacity. The most common example of mass storage 309 is a hard disk drive. Mass storage 305 and 309 generally store additional programming instructions, data, and the like that typically are not in active use by the processing subsystem. It will be appreciated that the information retained within mass storage 305 and 309 may be incorporated, if needed, in standard fashion as part of primary storage 304 (e.g. RAM) as virtual memory.

In addition to providing processing subsystem 301 access to storage subsystems, bus 306 can be used to provide access other subsystems and devices as well. In the described embodiment, these can include a display monitor 308, a network interface 307, a keyboard 302, and a pointing device 303, as well as an auxiliary input/output device interface, a sound card, speakers, and other subsystems as needed. The pointing device 303 may be a mouse, stylus, track ball, or tablet, and is useful for interacting with a graphical user interface. The network interface 307 allows the processing subsystem 301 to be coupled to another computer, computer network, or telecommunications network using a network connection as shown. Through the network interface 307, it is contemplated that the processing subsystem 301 might receive information, e.g., data objects or program instructions, from another network, or might output information to another network in the course of performing the above-described method steps. Information, often represented as a sequence of instructions to be executed on a processing subsystem, may be received from and outputted to another network, for example, in the form of a computer data signal embodied in a carrier wave. An interface card or similar device and appropriate software implemented by processing subsystem 301 can be used to connect the computer system 300 to an external network and transfer data according to standard protocols. That is, method embodiments of the present invention may execute solely upon processing subsystem 301, or may be performed across a network such as the Internet, intranet networks, or local area networks, in conjunction with a remote processing subsystem that shares a portion of the processing. Additional mass storage devices (not shown) may also be connected to processing subsystem 301 through network interface 307.

An auxiliary I/O device interface (not shown) can be used in conjunction with computer system 300. The auxiliary I/O device interface can include general and customized interfaces that allow the processing subsystem 301 to send and, more typically, receive data from other devices such as microphones, touch-sensitive displays, transducer card readers, tape readers, voice or handwriting recognizers, biometrics readers, cameras, portable mass storage devices, and other computers.

In addition, embodiments of the present invention further relate to computer storage products with a computer readable medium that contains program code for performing various computer-implemented operations. The computer-readable medium is any data storage device that can store data which can thereafter be read by a computer system. The media and program code may be those specially designed and constructed for the purposes of the present invention, or they may be of the kind well known to those of ordinary skill in the computer software arts. Examples of computer-readable media include, but are not limited to, all the media mentioned above: magnetic media such as hard disks, floppy disks, and magnetic tape; optical media such as CD-ROM disks; magneto-optical media such as floptical disks; and specially configured hardware devices such as application-specific integrated circuits (ASICs), programmable logic devices (PLDs), and ROM and RAM devices. The computer-readable medium can also be distributed as a data signal embodied in a carrier wave over a network of coupled computer systems so that the computer-readable code is stored and executed in a distributed fashion. Examples of program code include both machine code, as produced, for example, by a compiler, or files containing higher level code that may be executed using an interpreter. The computer system shown in FIG. 3 is but an example of a computer system suitable for use with the invention. Other computer systems suitable for use with the invention may include additional or fewer subsystems. In addition, bus 306 is illustrative of any interconnection scheme serving to link the subsystems. Other computer architectures having different configurations of subsystems may also be utilized.

### EXAMPLES

### Example 1: Checkerboard Pattern

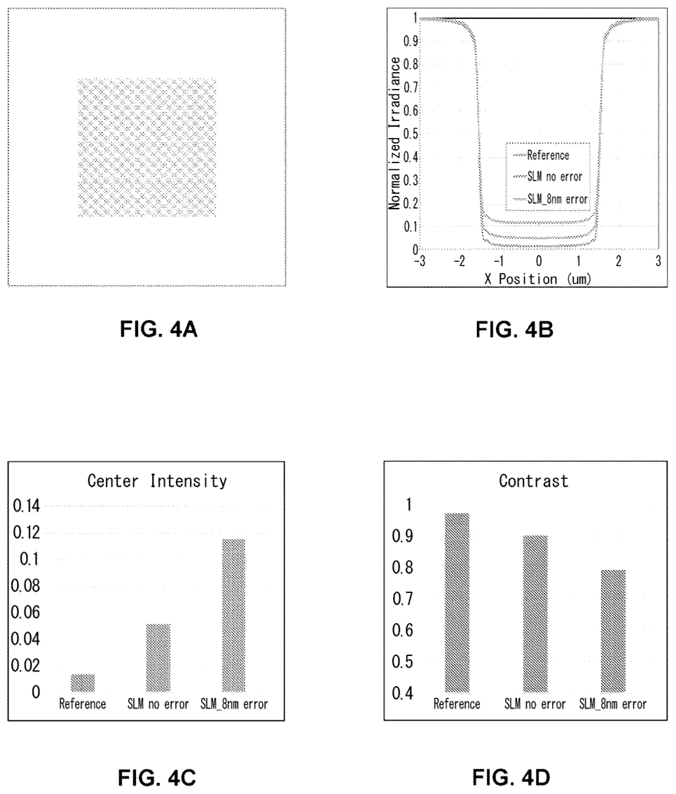

FIG. 4A shows an example of a checkerboard SLM pattern or reference modulation pattern described herein. In the example shown, the checkerboard pattern utilized a series of dark squares and a series of light squares. Each of the dark squares and the light squares constituted a 36 nanometer (nm) by 36 nm area and were separated from other squares by a 4 nm gap. The dark squares and lights squares were arranged in a checkerboard pattern that covered a 3 μm by 3 μm area. The test pattern was arranged on a 6 μm by 6 μm substrate. FIG. 4B shows an example of simulated irradiance profiles obtained after passing light through the checkerboard pattern of FIG. 4A. FIG. 4C shows an example of simulated center intensities of the irradiance profiles of FIG. 4B. FIG. 4D shows an example of simulated contrasts of the irradiance profiles of FIG. 4C. As shown in FIGS. 4B-4D, a reference plate alone produces a sharp irradiance profile with minimal losses. A reference plate combined with an SLM suffering no errors produces a less sharp irradiance profile with increased losses. A reference plate with a SLM suffering from phase errors resulting from an 8 nm micromirror position error produces an even less sharp irradiance profile with even higher losses.

### Recitation of Embodiments

Embodiment 1. A system for monitoring spatial light modulator (SLM) flare in a maskless photolithography system, comprising:
a stage configured to support an SLM and a reference plate, the stage movable between:
   a first position in which the SLM receives source light, imparts an SLM pattern thereon, and projects spatially modulated light based on the SLM pattern, the spatially modulated light comprising a first flare pattern associated with the SLM; and
   a second position in which the reference plate receives the source light, imparts a reference modulation pattern thereon, and projects reference modulated light based on the reference modulation pattern, the reference modulated light comprising a second flare pattern associated with the reference plate;
a projection lens configured to:
   when the stage is in the first position, receive the spatially modulated light and project a first image corresponding to the spatially modulated light;
   when the stage is in the second position, receive the reference modulated light and project a second image corresponding to the reference modulated light;
   an aerial imaging system configured to:
   when the stage is in the first position, receive the first image and output a first signal corresponding thereto; and
   when the stage is in the second position, receive the second image and output a second signal corresponding thereto; and
a controller operably coupled to the stage and to the aerial imaging system, the controller configured to:
   (a) direct the stage to move to the first position;
   (b) receive the first signal;
   (c) direct the stage to move to the second position;
   (d) receive the second signal; and
   (e) determine a third flare pattern associated with SLM errors based on a difference between the first signal and the second signal.

Embodiment 2. The system of Embodiment 1, further comprising a light source configured to project the source light.

Embodiment 3. The system of Embodiment 1 or 2, wherein the controller is further operably coupled to the SLM and wherein the controller is further configured to alter one or more parameters associated with the SLM in response to the third flare pattern.

Embodiment 4. The system of Embodiment 3, wherein the one or more parameters comprise one or more members selected from the group consisting of: an exposure time of the spatially modulated light on a photoresist, an exposure intensity of the spatially modulated light on a photoresist, and a phase of one or more pixels associated with the SLM.

Embodiment 5. The system of any one of Embodiments 1-4, wherein the reference modulation pattern comprises a static modulation pattern.

Embodiment 6. The system of any one of Embodiments 1-5, wherein the aerial imaging system comprises at least one deep ultraviolet (DUV) camera.

Embodiment 7. The system of any one of Embodiments 1-6, wherein the SLM pattern or the reference modulation pattern is selected from the group consisting of: a checkerboard pattern, a flat line pattern, a parallelogram pattern, a diamond pattern, and a pattern comprising at least one alignment mark.

Embodiment 8. The system of any one of Embodiments 1-7, wherein the source light comprises OBKK light or BBSK light.

Embodiment 9. The system of any one of Embodiments 1-8, wherein the controller comprises:
a processor; and
a memory coupled with the processor, wherein the memory is configured to provide the processor with instructions which when executed cause the processor to perform (a)-(e). Embodiment 10. The system of any one of Embodiments 1-8, wherein the controller comprises:

a processor configured to perform (a)-(e); and a memory coupled to the processor and configured to provide the processor with instructions to perform (a)-(e).

Embodiment 11. A method for monitoring spatial light modulator (SLM) flare in a maskless photolithography system, comprising:
(a) projecting source light to an SLM, thereby imparting an SLM pattern thereon and projecting spatially modulated light based on the SLM pattern, the spatially modulated light comprising a first flare pattern associated with the SLM;
(b) using a projection lens to receive the spatially modulated light and to project a first image corresponding to the spatially modulated light;
(c) using an aerial imaging system to receive the first image and to output a first signal corresponding thereto;
(d) projecting the source light to a reference plate, thereby imparting a reference modulate pattern thereon and projecting reference modulated light based on the reference modulation pattern, the reference modulated light comprising a second flare pattern associated with the reference plate;
(e) using the projection lens to receive the reference modulated light and to project a second image corresponding to the reference modulated light;
(f) using the aerial imaging system to receive the second image and to output a second signal corresponding thereto; and
(g) determining a third flare pattern associated with SLM errors based on a difference between the first signal and the second signal.

Embodiment 12. The method of Embodiment 11, further comprising using a light source to project the source light.

Embodiment 13. The method of Embodiment 11 or 12, further comprising altering one or more parameters associated with the SLM in response to the third flare pattern.

Embodiment 14. The method of Embodiment 13, wherein the one or more parameters comprise one or more members selected from the group consisting of: an exposure time of the spatially modulated light on a photoresist, an exposure intensity of the spatially modulated light on a photoresist, and a phase of one or more pixels associated with the SLM.

Embodiment 15. The method of any one of Embodiments 11-14, wherein the reference modulation pattern comprises a static modulation pattern.

Embodiment 16. The method of any one of Embodiments 11-15, wherein the aerial imaging system comprises at least one deep ultraviolet (DUV) camera.

Embodiment 17. The method of any one of Embodiments 11-16, wherein the SLM pattern or the reference modulation pattern is selected from the group consisting of: a checkerboard pattern, a flat line pattern, a parallelogram pattern, a diamond pattern, and a pattern comprising at least one alignment mark.

Embodiment 18. An exposure apparatus comprising:
an illumination optical system configured to illuminate a spatial light modulator (SLM) which has a plurality of SLM elements having a reflecting surface disposed on a disposition plane;
a projection optical system configured to project light from the SLM to a workpiece;
a reference member having a reference modulation pattern;
a position changing apparatus configured to change a positional relationship among the SLM, the reference member, and the projection optical system to either a first positional relationship in which a light from the illumination optical system enters in the projection optical system via the SLM and a second positional relationship in which a light from the illumination optical system enters in the projection optical system via the reference member; and
a detection apparatus configured to detect a light from the SLM or the reference member via the projection optical system.

Embodiment 19. The exposure apparatus of Embodiment 18, further comprising a calculation apparatus configured to calculate a state of the SLM based on a first output from the detection apparatus in the first positional relationship and a second output from the detection apparatus in the second positional relationship.

Embodiment 20. The exposure apparatus of Embodiment 19, wherein the state of the SLM comprises a flare from the SLM.

Embodiment 21. The exposure apparatus of any one of Embodiments 18-20, wherein the detection apparatus is configured to detect an aerial image of the SLM and the reference modulation pattern of the reference member formed by the projection optical system.

Embodiment 22. The exposure apparatus of Embodiment 21, wherein the detection apparatus is configured to detect the aerial image of the SLM in the first positional relationship, and to detect the aerial image of the reference modulation pattern in the second positional relationship.

Embodiment 23. The exposure apparatus of any one of Embodiments 18-22, further comprising a controller configured to control a pattern of the plurality of SLM elements and the position changing apparatus.

Embodiment 24. The exposure apparatus of Embodiment 23, wherein the controller is configured to set the pattern of the plurality of SLM elements to the same pattern as the reference modulation pattern.

Embodiment 25. The exposure apparatus of any one of Embodiments 18-24, wherein the reference modulation pattern comprises at least one of a checkerboard pattern, a flat line pattern, a parallelogram pattern, a diamond pattern, and a pattern comprising at least one alignment mark.

Embodiment 26. An exposure method comprising:
illuminating a spatial light modulator (SLM) which has a plurality of SLM elements having a reflecting surface disposed on a disposition plane;
using a projection optical system to project a light from the SLM to a workpiece;
setting a positional relationship between the SLM and the projection optical system to a first positional relationship in which a light from the SLM enters in the projection optical system;
outputting a first output by detecting a light from the SLM via the projection optical system in the first positional relationship;
setting a positional relationship between a reference member having a reference modulation pattern and the projection optical system to a second positional relationship in which a light from the reference member enters in the projection optical system; and
outputting a second output by detecting a light from the SLM via the projection optical system in the second positional relationship.

Embodiment 27. The exposure method of Embodiment 26, further comprising obtaining a state of the SLM based on the first and second output.

Embodiment 28. A device manufacturing method comprising:
forming a resist on a surface of a substrate; and
exposing an exposure pattern using the exposure method of Embodiment 26 or 27.

Incidentally, as long as the national laws in designated states (or elected states), to which this international application is applied, permit, the above disclosures of all the publications (including the pamphlet of the International Publications) and the U.S. Patents related to the exposure apparatus quoted in each of the embodiments above and in the modified examples are incorporated herein by reference.

What is claimed is:

1. A system for monitoring spatial light modulator (SLM) flare in a maskless photolithography system, comprising:
a stage configured to support an SLM and a reference plate, the stage movable between:
a first position in which the SLM receives source light, imparts an SLM pattern thereon, and projects spatially modulated light based on the SLM pattern, the spatially modulated light comprising a first flare pattern associated with the SLM; and
a second position in which the reference plate receives the source light, imparts a reference modulation pattern thereon, and projects reference modulated light based on the reference modulation pattern, the reference modulated light comprising a second flare pattern associated with the reference plate;
a projection lens configured to:
when the stage is in the first position, receive the spatially modulated light and project a first image corresponding to the spatially modulated light;
when the stage is in the second position, receive the reference modulated light and project a second image corresponding to the reference modulated light;
an aerial imaging system configured to:
when the stage is in the first position, receive the first image and output a first signal corresponding thereto; and
when the stage is in the second position, receive the second image and output a second signal corresponding thereto; and
a controller operably coupled to the stage and to the aerial imaging system, the controller configured to:
(a) direct the stage to move to the first position;
(b) receive the first signal;
(c) direct the stage to move to the second position;
(d) receive the second signal; and
(e) determine a third flare pattern associated with SLM errors based on a difference between the first signal and the second signal.

2. The system of claim 1, further comprising a light source configured to project the source light.

3. The system of claim 1, wherein the controller is further operably coupled to the SLM and wherein the controller is further configured to alter one or more parameters associated with the SLM in response to the third flare pattern.

4. The system of claim 3, wherein the one or more parameters comprise one or more members selected from the group consisting of: an exposure time of the spatially modulated light on a photoresist, an exposure intensity of the spatially modulated light on a photoresist, and a phase of one or more pixels associated with the SLM.

5. The system of claim 1, wherein the reference modulation pattern comprises a static modulation pattern.

6. The system of claim 1, wherein the aerial imaging system comprises at least one deep ultraviolet (DUV) camera.

7. The system of claim 1, wherein the SLM pattern or the reference modulation pattern is selected from the group consisting of: a checkerboard pattern, a flat line pattern, a parallelogram pattern, a diamond pattern, and a pattern comprising at least one alignment mark.

8. The system of claim 1, wherein the source light comprises OBKK light or BBSK light.

9. The system of claim 1, wherein the controller comprises:
a processor; and
a memory coupled with the processor, wherein the memory is configured to provide the processor with instructions which when executed cause the processor to perform (a)-(e).

10. The system of claim 1, wherein the controller comprises:
a processor configured to perform (a)-(e); and
a memory coupled to the processor and configured to provide the processor with instructions to perform (a)-(e).

11. A method for monitoring spatial light modulator (SLM) flare in a maskless photolithography system, comprising:
(a) projecting source light to an SLM, thereby imparting an SLM pattern thereon and projecting spatially modulated light based on the SLM pattern, the spatially modulated light comprising a first flare pattern associated with the SLM;
(b) using a projection lens to receive the spatially modulated light and to project a first image corresponding to the spatially modulated light;
(c) using an aerial imaging system to receive the first image and to output a first signal corresponding thereto;
(d) projecting the source light to a reference plate, thereby imparting a reference modulate pattern thereon and projecting reference modulated light based on the reference modulation pattern, the reference modulated light comprising a second flare pattern associated with the reference plate;
(e) using the projection lens to receive the reference modulated light and to project a second image corresponding to the reference modulated light;
(f) using the aerial imaging system to receive the second image and to output a second signal corresponding thereto; and
(g) determining a third flare pattern associated with SLM errors based on a difference between the first signal and the second signal.

12. The method of claim 11, further comprising using a light source to project the source light.

13. The method of claim 11, further comprising altering one or more parameters associated with the SLM in response to the third flare pattern.

14. The method of claim 13, wherein the one or more parameters comprise one or more members selected from the group consisting of: an exposure time of the spatially modulated light on a photoresist, an exposure intensity of the spatially modulated light on a photoresist, and a phase of one or more pixels associated with the SLM.

15. The method of claim 11, wherein the reference modulation pattern comprises a static modulation pattern.

16. The method of claim 11, wherein the aerial imaging system comprises at least one deep ultraviolet (DUV) camera.

17. The method of claim 11, wherein the SLM pattern or the reference modulation pattern is selected from the group consisting of: a checkerboard pattern, a flat line pattern, a parallelogram pattern, a diamond pattern, and a pattern comprising at least one alignment mark.

18. An exposure apparatus comprising:
an illumination optical system configured to illuminate a spatial light modulator (SLM) which has a plurality of SLM elements having a reflecting surface disposed on a disposition plane;
a projection optical system configured to project light from the SLM to a workpiece;
a reference member having a reference modulation pattern;
a position changing apparatus configured to change a positional relationship among the SLM, the reference member, and the projection optical system to either a first positional relationship in which a light from the illumination optical system enters in the projection optical system via the SLM and a second positional relationship in which a light from the illumination optical system enters in the projection optical system via the reference member; and
a detection apparatus configured to detect a light from the SLM or the reference member via the projection optical system.

19. The exposure apparatus of claim 18, further comprising a calculation apparatus configured to calculate a state of the SLM based on a first output from the detection apparatus in the first positional relationship and a second output from the detection apparatus in the second positional relationship.

20. The exposure apparatus of claim 19, wherein the state of the SLM comprises a flare from the SLM.

21. The exposure apparatus of claim 18, wherein the detection apparatus is configured to detect an aerial image of the SLM and the reference pattern of the reference member formed by the projection optical system.

22. The exposure apparatus of claim 21, wherein the detection apparatus is configured to detect the aerial image of the SLM in the first positional relationship, and to detect the aerial image of the reference modulation pattern in the second positional relationship.

23. The exposure apparatus of claim 18, further comprising a controller configured to control a pattern of the plurality of SLM elements and the position changing apparatus.

24. The exposure apparatus of claim 23, wherein the controller is configured to set the pattern of the plurality of SLM elements to the same pattern as the reference modulation pattern.

25. The exposure apparatus of claim 18, wherein the reference modulation pattern comprises at least one of a checkerboard pattern, a flat line pattern, a parallelogram pattern, a diamond pattern, and a pattern comprising at least one alignment mark.

26. An exposure method comprising:
illuminating a spatial light modulator (SLM) which has a plurality of SLM having a reflecting surface disposed on a disposition plane;
using a projection optical system to project a light from the SLM to a workpiece;
setting a positional relationship between the SLM and the projection optical system to a first positional relationship in which a light from the SLM enters in the projection optical system;
outputting a first output by detecting a light from the SLM via the projection optical system in the first positional relationship;
setting a positional relationship between a reference member having a reference modulation pattern and the projection optical system to a second positional relationship in which a light from the reference member enters in the projection optical system; and
outputting a second output by detecting a light from the SLM via the projection optical system in the second positional relationship.

27. The exposure method of claim 26, further comprising obtaining a state of the SLM based on the first and second output.

28. A device manufacturing method comprising:
forming a resist on a surface of a substrate; and
exposing an exposure pattern using the exposure method of claim 26.
